(19) United States
(12) Patent Application Publication
(10) Pub. No.: US 2011/0006443 A1
(43) Pub. Date: Jan. 13, 2011

(54) SEMICONDUCTOR DEVICE

(75) Inventors: Koichiro Noguchi, Minato-ku (JP); Yoshio Kameda, Minato-ku (JP); Yoshihiro Nakagawa, Minato-ku (JP); Masayuki Mizuno, Minato-ku (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Tokyo (JP)

(21) Appl. No.: 12/920,452

(22) PCT Filed: Feb. 19, 2009
(86) PCT No.: PCT/JP2009/052923

§ 371 Date: Aug. 31, 2010

(30) Foreign Application Priority Data
Mar. 13, 2008 (JP) 2008-064164

(51) Int. Cl. H01L 23/48

(52) U.S. Cl. 257/786; 257/E23.01

(57) ABSTRACT

Disclosed is a semiconductor device composed of a plurality of semiconductor integrated circuits and a plurality of coils. During the production process of the semiconductor device, the plurality of coils are so arranged that the coil surfaces are generally perpendicular to the front surface of a chip of the semiconductor integrated circuits wherein metal films are laminated. A signal is transmitted between a pair of adjacent coils among the plurality of coils.

### TECHNICAL FIELD

The present invention relates to a semiconductor device for transmitting signals.

### BACKGROUND ART

In recent years, the multichip module technology for integrating a plurality of chips in one package has been used in the art. For transmitting signals between the chips in a multichip module, it has been the practice to employ a method of directly connecting the chips physically by way of wire bonding for signal transmission therebetween and also a method of combining capacitors and coils with the chips that are closely integrated for contactless signal transmission therebetween.

Particularly, there have been proposed means for performing contactless signal transmission with coils between LSI chips that are stacked semiconductor integrated circuits (see, for example, JP No. 2005-203657A and JP No. 2006-105630A). According to these technologies, a current with superimposed data is supplied to a sending coil on a silicon substrate, inducing electric power in a receiving coil through an electromagnetic coupling for thereby performing contactless signal transmission. In particular, one or more coils whose coil planes lie substantially parallel to the surface of an LSI chip are disposed in the LSI chip, and a plurality of stacked chips perform contactless signal transmission in a direction substantially perpendicular to the surfaces of the chips.

However, the above technologies pose two problems described below.

The first problem is that if coils are used to perform signal transmission substantially parallel to the chip surfaces, then the coils whose coil planes lie substantially parallel to the chip surfaces take up a large area for communications. Since the direction of magnetic fluxes produced by the coils is substantially perpendicular to the coil planes, the coils arranged such that their coil planes lie substantially parallel to the chip surfaces cause the generated magnetic fluxes to be directed perpendicularly to the direction of communications. Consequently, the generated magnetic fluxes cannot effectively be utilized.

The second problem is that the coils used for signal transmission adversely affect coils that are disposed in the chips for other purposes, tending to lower the performance of the chips in their entirety. Usually, various chips are integrated in chips. For example, oscillating circuits and antenna circuits for RF communications incorporate high-precision coils whose parameters are carefully adjusted. Therefore, the magnetic fluxes generated by the signal transmission coils tend to leak into those high-precision coils, changing the characteristics thereof. Accordingly, circuit performance is caused to deteriorate, resulting in a margin reduction and operation failure of the chips as a whole.

### DISCLOSURE OF THE INVENTION

It is an object of the present invention to provide a semiconductor device which will solve the above problems.

To achieve the above object, there is provided in accordance with the present invention a semiconductor device comprising a plurality of semiconductor integrated circuits and a plurality of coils, wherein said coils are arranged such that coil planes thereof lie substantially perpendicular to chips surfaces of said semiconductor integrated circuits on which metal films are stacked in a process of fabricating the semiconductor devices, and a signal is transmitted between a pair of adjacent ones of said coils.

According to the present invention, as described above, in a semiconductor device comprising a plurality of semiconductor integrated circuits and a plurality of coils, the coils are arranged such that coil planes thereof lie substantially perpendicular to chips surfaces of the semiconductor integrated circuits on which metal films are stacked in a process of fabricating the semiconductor devices, and a signal is transmitted between a pair of adjacent ones of the coils. Consequently, the coils are reduced in area and an adverse effect which the coils have on other coils disposed in chips is reduced.

### BRIEF DESCRIPTION OF THE DRAWINGS

FIG. 1 is a view showing a first exemplary embodiment of the present invention;

FIG. 2 is a view showing signal transmission coils disposed in LSI chips;

FIG. 3 is a view showing an example of a manufactured coil that is disposed in a semiconductor device;

FIG. 4 is a circuit diagram of internal circuits of LSI chips for sending and receiving signals;

FIG. 5 is a diagram showing the operational waveforms of signals in the circuits shown in FIG. 4;

FIG. 6 is a view showing another example of a manufactured coil;

FIG. 7 is a view showing a second exemplary embodiment of the present invention;

FIG. 8 is a view showing a third exemplary embodiment of the present invention;

FIG. 9a is a view showing a fourth exemplary embodiment of the present invention;

FIG. 9b is a view showing the fourth exemplary embodiment of the present invention;

FIG. 10a is a view showing a fifth exemplary embodiment of the present invention;

FIG. 10b is a view showing the fifth exemplary embodiment of the present invention;

FIG. 11a is a view showing a sixth exemplary embodiment of the present invention;

FIG. 11b is a view showing the sixth exemplary embodiment of the present invention; and

FIG. 11c is a view showing the sixth exemplary embodiment of the present invention.

### BEST MODE FOR CARRYING OUT THE INVENTION

Exemplary embodiments of the present invention will be described below with reference to the drawings.

### First Exemplary Embodiment

### Description of the Structure

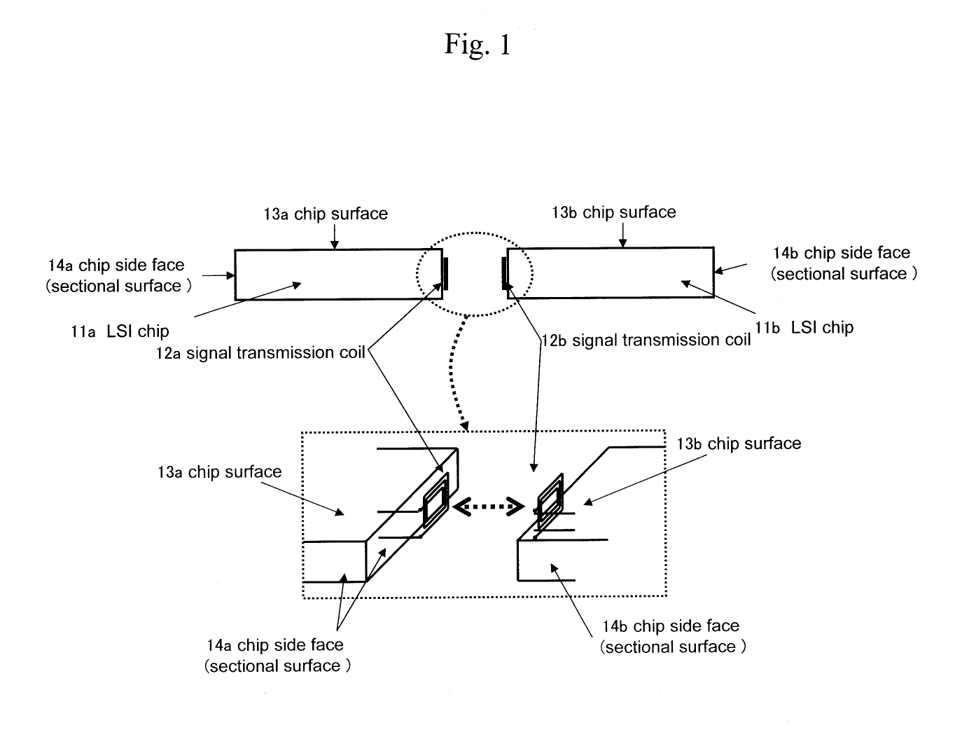

FIG. 1 is a view showing a first exemplary embodiment of the present invention.

As shown in FIG. 1, the present exemplary embodiment comprises two LSI chips 11a, 11b disposed adjacent to each other, with respective chip side faces 14a, 14b facing each other. LSI chips 11a, 11b which perform signal transmission therebetween have signal transmission coils 12a, 12b disposed therein. Signal transmission coils 12a, 12b are arranged such that their coil planes lie substantially perpendicular to chip surfaces 13a, 13b. The area of the coil plane of signal transmission coil 12a and the area of the coil plane of signal transmission coil 12 may be equal to each other.

Signal transmission coils 12a, 12b arranged according to the present exemplary embodiment are capable of generating magnetic fluxes in a direction substantially parallel to chip surfaces 13a, 13b. Therefore, for signal transmission in the direction substantially parallel to chip surfaces 13a, 13b, the coupling between the coils is stronger than with the coil arrangement according to the background art, and it is possible to achieve contactless signal transmission between LSI chips 11a, 11b disposed adjacent to each other with coils having a smaller area than with the coil arrangement according to the background art.

The definitions of certain terms used in the present description will be described below.

The term “substantially perpendicular” may refer to a plane which is inclined to a certain extent depending on manufacturing errors or the direction of communications, rather than a plane which is completely perpendicular (90 degrees) to a certain surface. Similarly, the terms “substantially horizontal” and “substantially parallel” may refer to a plane which is inclined to a certain extent depending on manufacturing errors or the direction of communications, rather than a plane which is completely parallel to a certain surface (which does not cross a certain surface even if extended infinitely).

The term “chip surface” refers to a surface which is substantially perpendicular to a sectional surface produced when a chip is diced from a wafer or a surface which is substantially parallel to a surface on which a metal film is deposited in the manufacturing process.

The term “coil plane” refers to a loop plane of a coil winding that is installed in a circular or polygonal pattern.

The term “coils arranged” according to the background art refers to coils which are arranged such that their coil planes lie substantially parallel to the chip surfaces.

### [Description of the Operation]

Signal transmission coils 12a, 12b that are disposed respectively in LSI chips 11a, 11b perform signal transmission through electromagnetic coupling. If signal transmission coils 12a, 12b operate as sending coils, then a sending coil sends a signal when it is supplied with a current with superimposed data, and the other receiving coil recovers the signal by detecting a potential that is induced therein by electromagnetic coupling. Signal transmission is realized by thus inducing a potential from the sending side to the receiving side.

### EXAMPLES

Best arrangements and operation thereof for carrying out the present invention will be described below with reference to specific examples.

According to an example, signal transmission coils disposed in LSI chips will be described below.

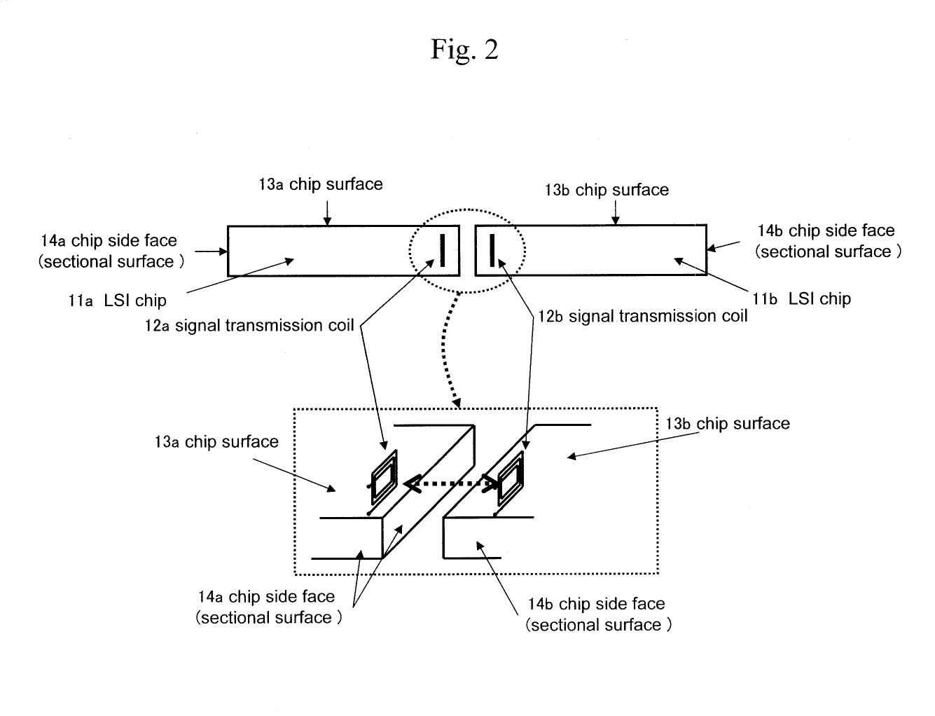

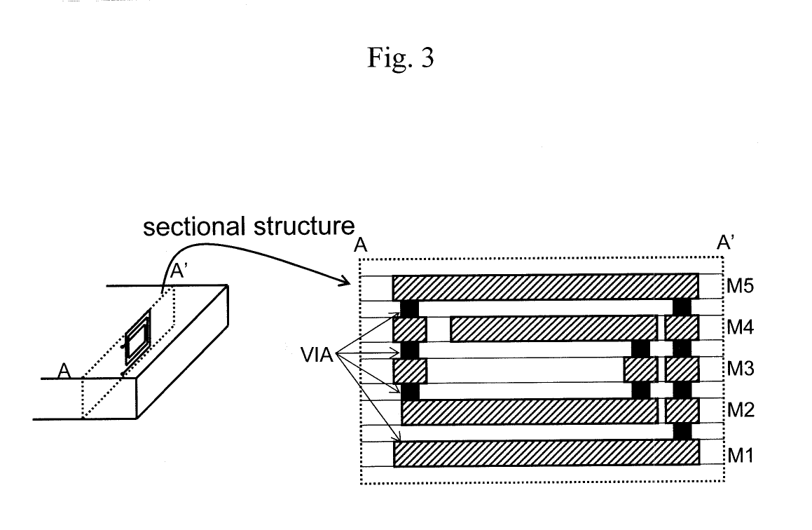

FIG. 2 is a view showing signal transmission coils disposed in LSI chips, and FIG. 3 is a view showing an example of a manufactured coil that is disposed in a semiconductor device.

According to the present example, as shown in FIG. 3, a coil that is disposed in a semiconductor device is produced by a normal semiconductor device fabrication process, using first through fifth metal interconnect layers (M1 through M5). Signal transmission coils 12a, 12b shown in FIG. 2 are designed such that they have a diameter of several tens micrometers, and are formed in ends of LSI chips 11a, 11b with their coil planes lying substantially perpendicular to chip surfaces 13a, 13b. LSI chips 11a, 11b for performing signal transmission therebetween are disposed adjacent to each other such that the distance between the coils is about twice the coil diameter. The coils may alternatively be disposed outside the LSI chips.

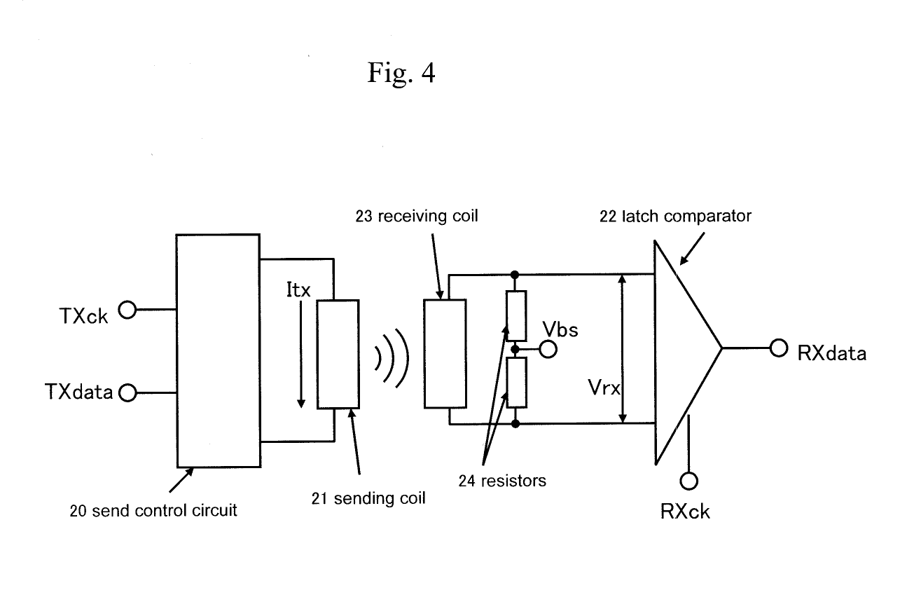

FIG. 4 is a circuit diagram of internal circuits of LSI chips 11a, 11b for sending and receiving signals.

As shown in FIG. 4, send control circuit 20 is connected to sending coil 21, and generates magnetic fluxes for signal transmission by supplying a current to sending coil 21 based on a transmission clock (TXck) and transmission data (TXdata). The magnetic fluxes make it possible to send a signal.

Latch comparator 22 is connected across receiving coil 23 and detects a voltage (Vrx) induced in receiving coil 23. Latch comparator 22 converts the detected voltage into digital signal (RXdata) in timed relation to reception clock (RXck) to detect the signal. Resistors 24 are inserted across receiving coil 23 to secure an intermediate potential for inducing a voltage in receiving coil 23.

Sending coil 21 shown in FIG. 4 corresponds to one of signal transmission coils 12a, 12b shown in FIGS. 1 and 2, and receiving coil 23 shown in FIG. 4 corresponds to the other of signal transmission coils 12a, 12b shown in FIGS. 1 and 2 which does not correspond to sending coil 21.

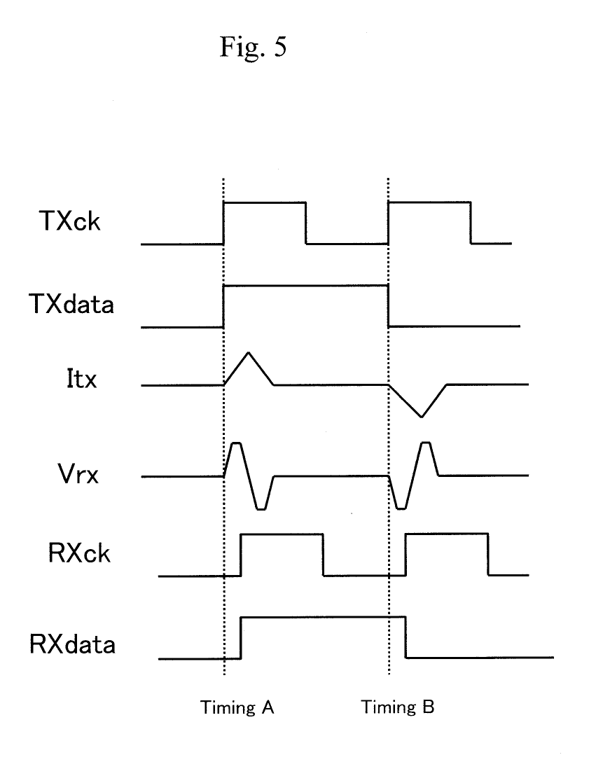

FIG. 5 is a diagram showing the operational waveforms of signals in the circuits shown in FIG. 4.

In FIG. 5, data “1” is sent and received at A timing, and data “0” is sent and received at B timing.

Sending coil 21 sends the value of TXdata at a positive-going edge of TXck. For sending data “1”, a positive current (Itx) is supplied to sending coil 21, and for sending data “0”, a negative current (Itx) is supplied to sending coil 21, so that sending coil 21 generates magnetic fluxes of different polarities based on the data to be sent.

Receiving coil 23 induces a voltage (Vrx) whose waveform is equivalent to the differentiated waveform of the sending current. After the voltage Vrx is amplified at a positive-going edge of RXck by latch converter 22, the voltage Vrx is converted into a digital value, thus recovering the sent data as received data (RXdata).

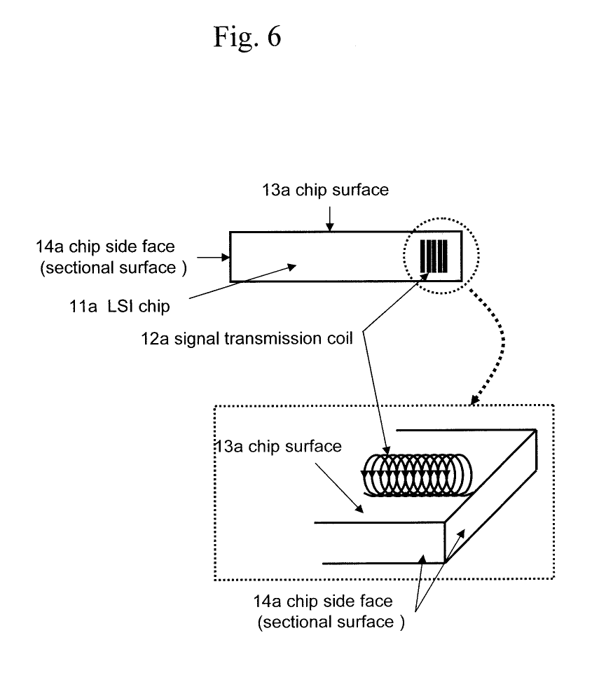

FIG. 6 is a view showing another example of a manufactured coil.

The other example of a manufactured coil shown in FIG. 6 can be manufactured by a normal fabrication process. Signal transmission coil 12a shown in FIG. 6 is of a helical shape, and is characterized in that the number of turns thereof in the depthwise direction is greater than the number of turns of the coil arranged according to the background art. This is because whereas the number of turns in the depthwise direction of the coil arranged according to the background art is limited by the number of interconnect layers, signal transmission coil 12a shown in FIG. 6 is free of such a limitation, and can have any desired number of turns. As the number of turns of signal transmission coil 12a is proportional to the intensity of magnetic fluxes generated thereby, it can generate stronger magnetic fluxes than the coil arranged according to the background art by increasing the number of turns, thereby realizing signals transmitted over an increased distance.

### Second Exemplary Embodiment

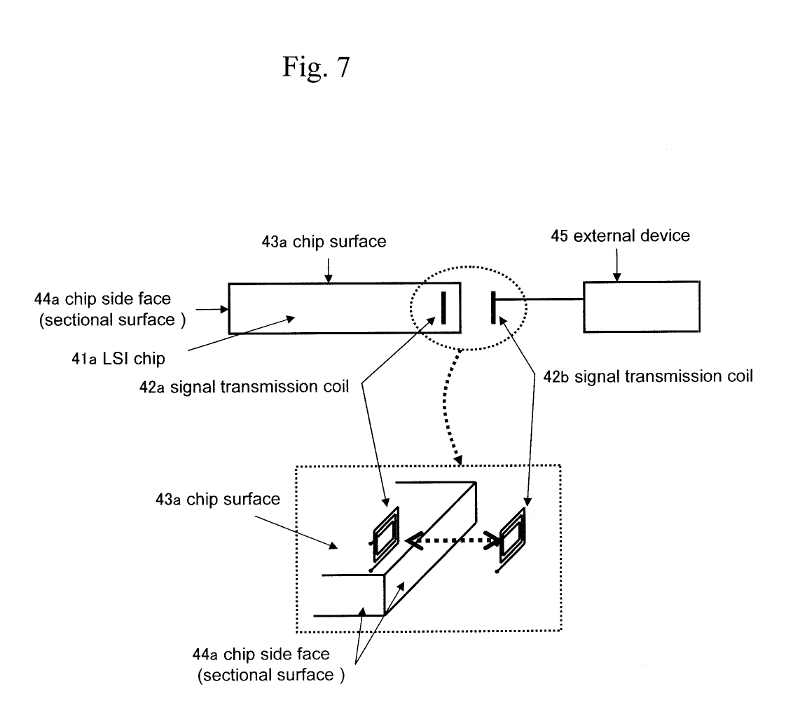

FIG. 7 is a view showing a second exemplary embodiment of the present invention.

As shown in FIG. 7, the present exemplary embodiment LSI chip 41a, signal transmission coil 42b, and external device 45. LSI chip 41a incorporates therein signal transmission coil 42a whose coil plane lies substantially perpendicular to chip surface 43a (substantially parallel to chip side face 44a). Signal transmission coil 42a is connected to a circuit shown in FIG. 4 which is disposed in the chip. Signal transmission coil 42b which is disposed outside the chip is arranged such that its coil plane lies substantially parallel to the coil plane of signal transmission coil 42a. Signal transmission coil 42b which is disposed outside the chip is connected to external device 45 for signal transmission control.

The present exemplary embodiment is characterized in that signal transmission coil 42b which lies substantially parallel to signal transmission coil 42a that lies substantially perpendicular to chip surface 43a is disposed outside the chip. The present exemplary embodiment is thus capable of realizing contactless signal transmission between LSI 41a and external device 45. The present exemplary embodiment is applicable to various applications wherein an external signal generator inputs a signal to a chip and the result of an operation of a chip is output to an external measuring instrument, for example.

### Third Exemplary Embodiment

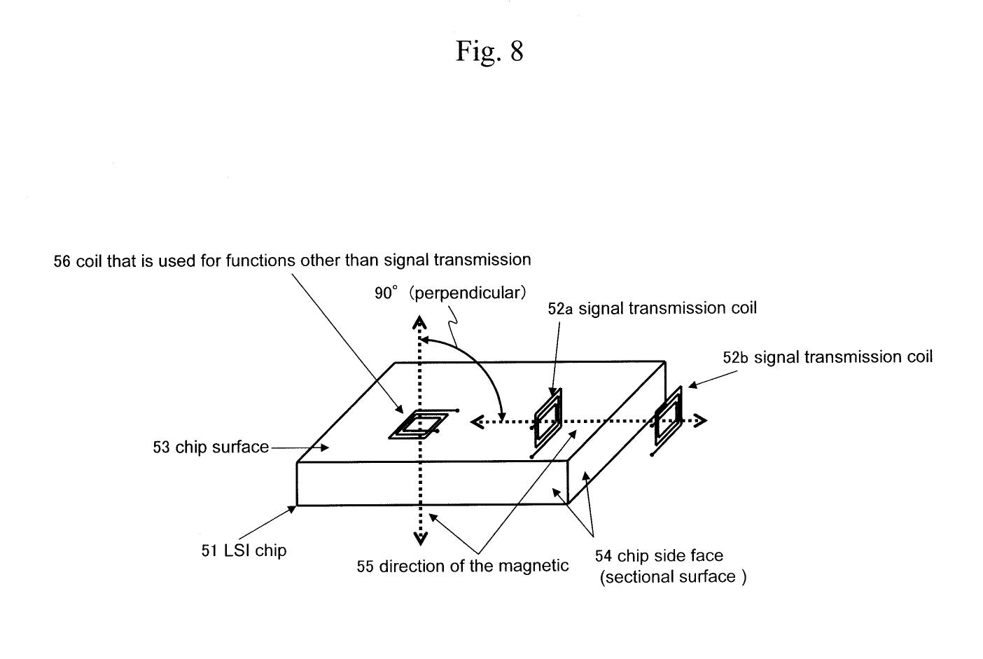

FIG. 8 is a view showing a third exemplary embodiment of the present invention.

As shown in FIG. 8, the present exemplary embodiment comprises LSI chip 51 and signal transmission coil 52b. LSI chip 51 incorporates therein coil 56, that is used for functions other than signal transmission, with its coil plane lying substantially parallel to chip side face 54, and signal transmission coil 52a whose coil plane lies lying substantially parallel to chip surface 53. Signal transmission coil 52a is arranged such that its coil plane lies substantially parallel to the coil plane of coil 56 that is used for functions other than signal transmission. Coils generate magnetic fluxes in a direction substantially perpendicular to their coil planes. The present exemplary embodiment is characterized in that the signal transmission coil is arranged such that direction 55 of the magnetic fluxes generated by signal transmission coil 52a and direction 55 of the magnetic fluxes generated by coil 56 that is used for functions other than signal transmission are perpendicular to each other.

Signal transmission coils 52a, 52b perform signal transmission therebetween through an electromagnetic coupling. The coils arranged according to the present exemplary embodiment make it possible to prevent the magnetic fluxes generated by signal transmission coil 52a from leaking into coil 56 that is used for functions other than signal transmission at the time of sending and receiving data. Consequently, a potential induced as noise in coil 56 that is used for functions other than signal transmission is reduced, thereby reducing its adverse effects on other functions. If the coils according to the present exemplary embodiment are used in RF chips, then the chips are capable of keeping a high performance level because any interference with flux leakages with RF signal reception antennas and oscillating circuits for frequency conversion is lowered.

### Fourth Exemplary Embodiment

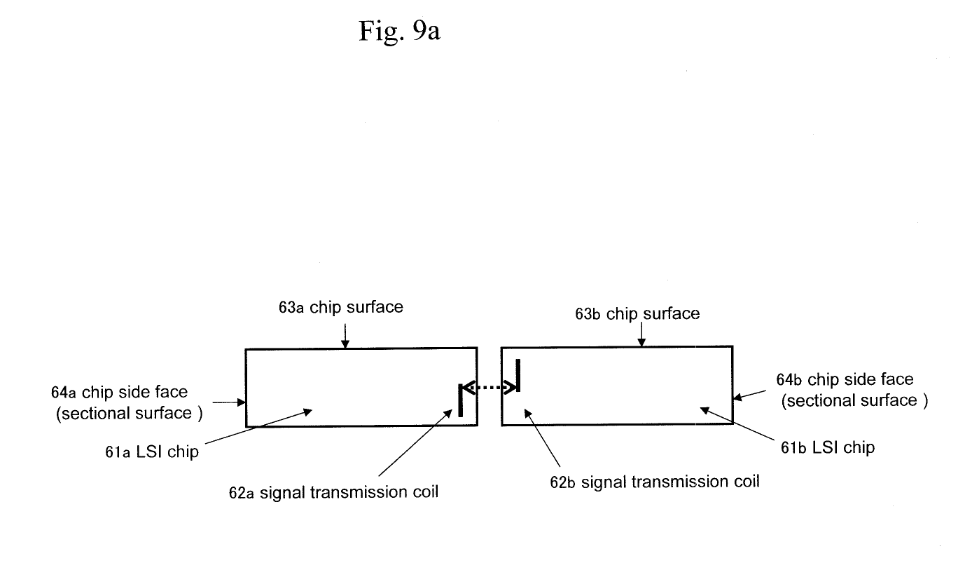

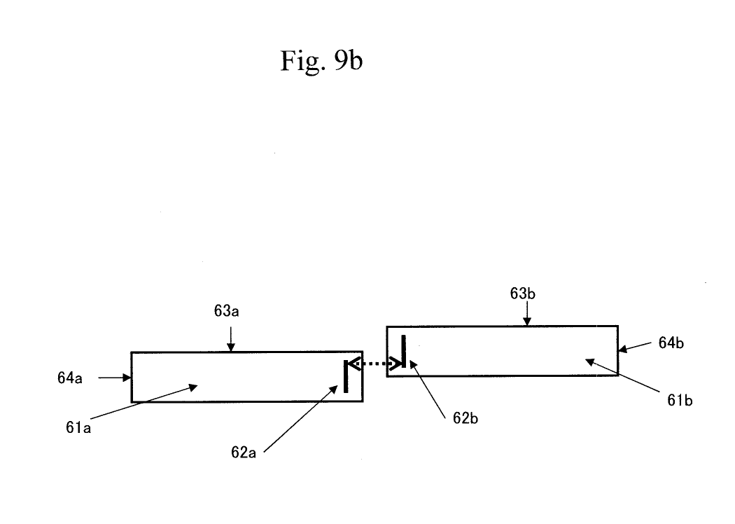

FIGS. 9a and 9b are views showing a fourth exemplary embodiment of the present invention.

As shown in FIGS. 9a and 9b, the present exemplary embodiment comprises LSI chips 61a, 61b. As described in the first exemplary embodiment, LSI chips 61a, 61b incorporate therein signal transmission coils 62a, 62b arranged such that their coil planes lie substantially perpendicular to chip surfaces 63a, 63b (their coil planes lie substantially parallel to chip side faces 64a, 64b). Signal transmission coils 62a, 62b shown in FIGS. 9a and 9b have respective central axes held out of alignment with each other.

FIG. 9a shows a configuration in which the coils are disposed in different positions in LSI chips 61a, 61b, holding their central axes out of alignment with each other. FIG. 9b shows a configuration in which the coils are disposed in the same positions in LSI chips 61a, 61b and LSI chips 61a, 61b are disposed in different positions, holding the central axes of the coils out of alignment with each other. Though the central axes of a pair of coils for performing signal transmission may be aligned with each other, the central axes of the coils may be slightly held out of alignment with each other according to the present exemplary embodiment. According to the present exemplary embodiment, though the central axes of the pair of coils for performing signal transmission are held out of alignment with each other, the angles of the coils from the direction of signal transmission are small, and the above principles are applicable to realize signal transmission.

The present exemplary embodiment takes into account situations wherein chips are disposed closely to each other and arranged such that their coils for performing signal transmission do not fully face each other, and provides a means for realizing signal transmission between the coils in more practical situations.

### Fifth Exemplary Embodiment

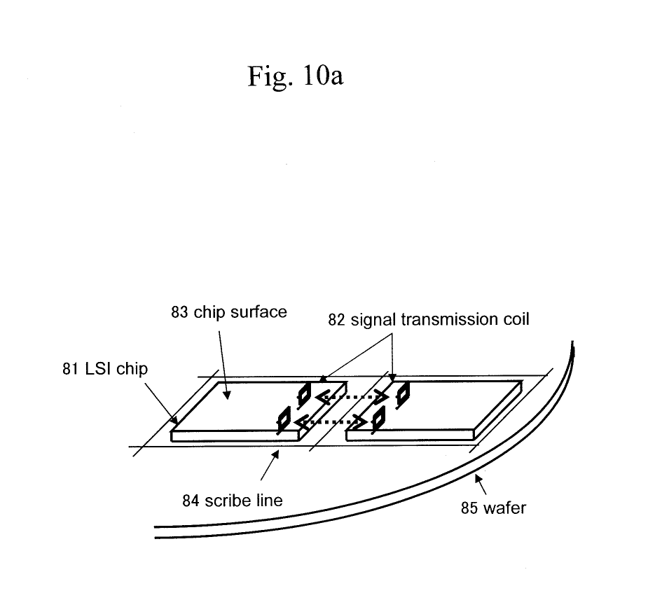

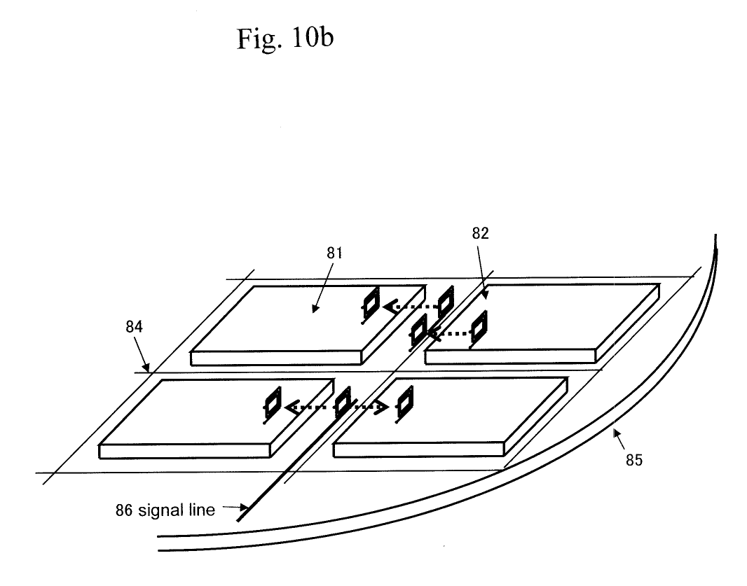

FIGS. 10a and 10b are views showing a fifth exemplary embodiment of the present invention.

As shown in FIGS. 10a and 10b, the present exemplary embodiment comprises a number of LSI chips 81 in wafer 85 before it is diced. Each of LSI chips 81 incorporates signal transmission coil 82 arranged such that its coil plane lies substantially perpendicular to chip surface 83. LSI chips 81 are disposed adjacent to each other across a scribe line (dicing line). Signal trans-mission coils 82 disposed in respective LSI chips 81 perform signal transmission through electromagnetic coupling.

The present exemplary embodiment is thus capable of realizing communications between the chips before the wafer is diced into the chips. FIG. 10a shows an example of signal transmission that is performed between LSI chips 81 across scribe line 84 through a plurality of signal transmission coils 82. FIG. 10b shows a configuration in which LSI chips 81 perform signal transmission through auxiliary coils on scribe line 84 and also a configuration in which LSI chips 81 send and receive signals through signal line 86 on scribe line 84 and signal transmission coils 82. In one of the configurations, the present exemplary embodiment is capable of signal trans-mission and can realize a chip inspection on a wafer.

### Sixth Exemplary Embodiment

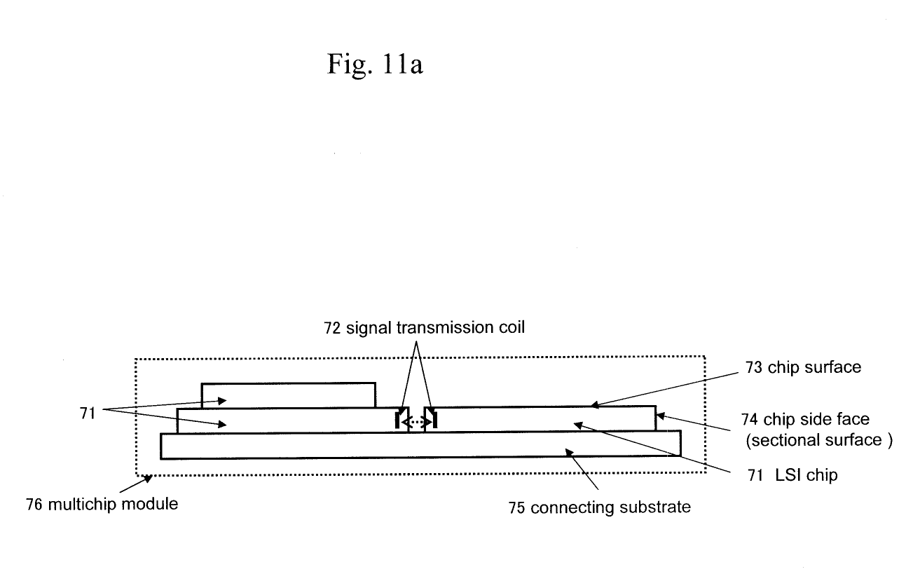

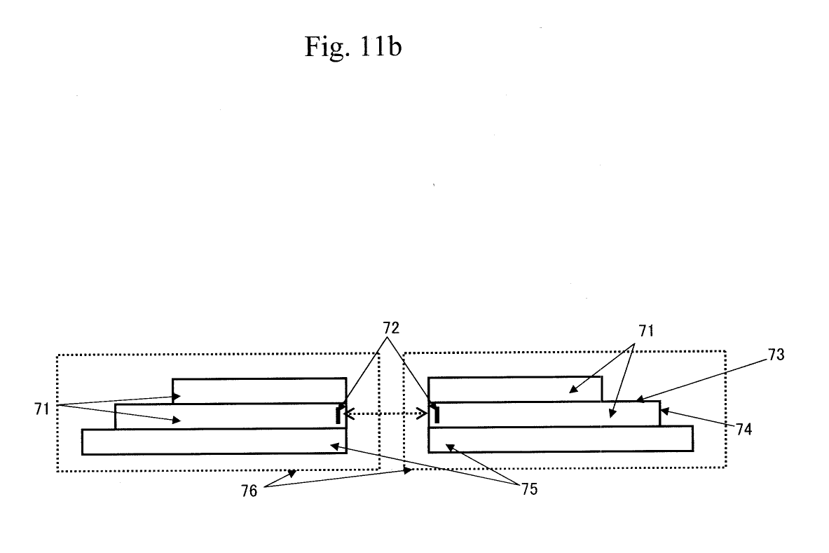

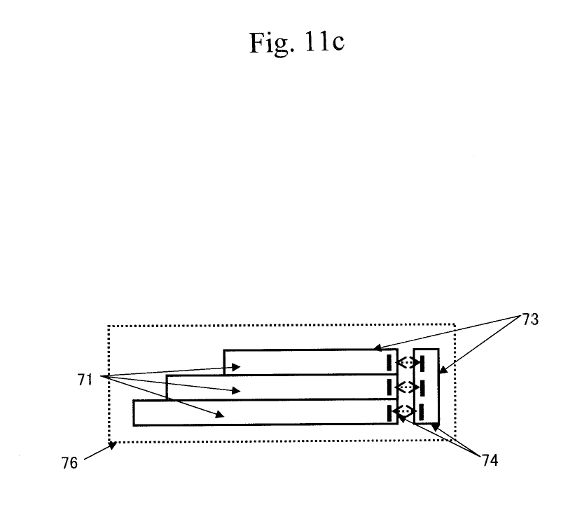

FIGS. 11a, 11b, and 11c are views showing a sixth exemplary embodiment of the present invention.

As shown in FIGS. 11a, 11b, and 11c, the present exemplary embodiment comprises multichip module 76 including a plurality of LSI chips 71 on connecting substrate 75. Signal trans-mission coils 72 are disposed in LSI chips 71 of multichip module 76. Signal transmission coils 72 are arranged such that their coil planes lie substantially perpendicular to chip surfaces 73 (their coil planes lie substantially parallel to chip faces 74).

FIG. 11a shows a configuration in which LSI chips 71 in multichip module 76 are disposed adjacent to each other. FIG. 11b shows a configuration in which signal transmission is performed between different multichip modules 76 in a direction substantially parallel to chip surfaces 76. FIG. 11c shows multichip module 76 in which LSI chips 71 having signal transmission coils 72 arranged to lie substantially perpendicular to chip surfaces 73 and an LSI chip having signal transmission coils 72 arranged to lie substantially parallel to chip surface 73 are arranged such that signal transmission coils 72 lie substantially parallel to each other.

In one of the configurations, signal transmission coils 72 perform signal transmission through an electromagnetic coupling. In multichip module 76, bonding wires and surface mount technology are used for signal communications between the chips. However, these technologies suffer packaging limitations because signals need to be extracted in a direction substantially perpendicular to the chip surfaces, and hence the chips cannot be stacked in the regions where the signals are extracted. According to the present exemplary embodiment, since contactless signal transmission is possible in a direction substantially parallel to the chip surfaces, it is possible to provide packaging techniques of high freedom as shown in FIGS. 11a, 11b, and 11c.

Applications of the present invention include use as communication interfaces for signal transmission in multichip modules and signal transmission for tests.

As described above, the present invention offers the following advantages:

The first advantage is that the coils can be reduced to a smaller area than the coils arranged to generate magnetic fluxes in a direction substantially parallel to the chip surfaces. This is because for signal transmission in a direction substantially parallel to the chip surfaces, the coils arranged according to the present invention generate magnetic fluxes in a direction substantially parallel to the chip surfaces.

The second advantage is that a leakage of magnetic fluxes into high-precision coils that have parameters carefully adjusted in applications other than signal transmission between chips is reduced to avoid a performance deterioration of oscillating circuits and antenna circuits for RF communications. This is because the direction of magnetic fluxes generated by coils arranged according to the present invention is perpendicular to the direction of a magnetic field generated by coils disposed in chips used for other than signal transmission between the chips.

The present invention has been described above in reference to the exemplary embodiments. However, the present invention is not limited to the above exemplary embodiments. Rather, various changes that can be understood by those skilled in the art within the scope of the invention may be made to the arrangements and details of the present invention.

The present application is based upon and claims the benefit of priority from Japanese patent application No. 2008-064164, filed on Mar. 13, 2008, the disclosure of which is incorporated herein in its entirety by reference.

1. A semiconductor device comprising a plurality of semiconductor integrated circuits and a plurality of coils, wherein said coils are arranged such that coil planes thereof lie substantially perpendicular to chips surfaces of said semiconductor integrated circuits on which metal films are stacked in a process of fabricating the semiconductor devices, and a signal is transmitted between a pair of adjacent ones of said coils.

2. The semiconductor device according to claim 1, wherein the coils of said pair have coil planes of equal areas.

3. The semiconductor device according to claim 1, wherein the coils of said pair have coil planes lying substantially parallel to each other.

4. (canceled)

5. (canceled)

6. The semiconductor device according to claim 2, wherein the coils of said pair have coil planes lying substantially parallel to each other.

7. The semiconductor device according to claim 1, wherein the coils of said pair have central axes held in alignment with each other.

8. The semiconductor device according to claim 2, wherein the coils of said pair have central axes held in alignment with each other.

9. The semiconductor device according to claim 3, wherein the coils of said pair have central axes held in alignment with each other.

10. The semiconductor device according to claim 1, wherein at least one of the coils of said pair is disposed in the semiconductor integrated circuits.

11. The semiconductor device according to claim 2, wherein at least one of the coils of said pair is disposed in the semiconductor integrated circuits.

12. The semiconductor device according to claim 3, wherein at least one of the coils of said pair is disposed in the semiconductor integrated circuits.

13. The semiconductor device according to claim 7, wherein at least one of the coils of said pair is disposed in the semiconductor integrated circuits.
